(19) United States
(12) Patent Application Publication
(10) Pub. No.: US 2023/0109650 A1
(43) Pub. Date: Apr. 6, 2023

(54) SEMICONDUCTOR DEVICE, SEMICONDUCTOR PACKAGE, AND METHODS FOR MANUFACTURING THESE

(71) Applicant: ROHM CO., LTD., Kyoto-shi, Kyoto (JP)

(72) Inventors: Yuki NAKANO, Kyoto-shi, Kyoto (JP); Yasunori KUTSUMA, Kyoto-shi, Kyoto (JP)

(73) Assignee: ROHM CO., LTD., Kyoto-shi, Kyoto (JP)

(21) Appl. No.: 17/911,424

(22) PCT Filed: Apr. 30, 2021
(86) PCT No.: PCT/JP2021/017270

§ 371 Date: Sep. 14, 2022

(30) Foreign Application Priority Data
May 8, 2020 (JP) 2020-082702

(51) Int. Cl. H01L 23/00; H01L 29/16; H01L 29/78

(52) U.S. Cl. CPC H01L 24/05; H01L 29/1608; H01L 29/7813; H01L 29/7804; H01L 24/45; H01L 24/03; H01L 2224/04042; H01L 2224/02215; H01L 2224/45; H01L 2224/03019

(57) ABSTRACT

A semiconductor device includes a semiconductor layer that has a first main surface at one side and a second main surface at another side, a first main surface electrode that includes a first electrode covering the first main surface and a second electrode having a higher hardness than the first electrode and covering the first electrode, and an oxide layer that covers the first main surface electrode.

### TECHNICAL FIELD

The present application corresponds to Japanese Patent Application No. 2020-082702 filed on May 8, 2020 in the Japan Patent Office, and the entire disclosure of this application is incorporated herein by reference. The present invention relates to a semiconductor device, a semiconductor package, and methods for manufacturing these.

### BACKGROUND ART

Patent Literature 1 discloses an art related to a vertical semiconductor element that uses an SiC semiconductor substrate.

### CITATION LIST

### Patent Literature

Patent Literature 1: Japanese Patent Application Publication No. 2012-79945

### SUMMARY OF INVENTION

### Technical Problem

A preferred embodiment of the present invention provides a semiconductor device, a semiconductor package, and methods for manufacturing these by which mechanical strength can be improved.

### Solution to Problem

A preferred embodiment of the present invention provides a semiconductor device that includes a vertical power semiconductor element, the semiconductor device including a semiconductor layer that has a first main surface and a second main surface at an opposite side to the first main surface and includes SiC as a main component, a first electrode layer that is formed on the first main surface side of the semiconductor layer, a second electrode layer that is formed on the first electrode layer, is electrically connected to a first terminal of the vertical power semiconductor element, and is harder than the first electrode layer, a third electrode layer that is formed on the second main surface side of the SiC semiconductor layer and is electrically connected to a second terminal of the vertical power semiconductor element, and an oxide layer that is formed on a front surface of the second electrode layer.

A preferred embodiment of the present invention provides a method for manufacturing a semiconductor device that includes a vertical power semiconductor element, the method for manufacturing the semiconductor device including a step of forming a first electrode layer at a first main surface side of a semiconductor layer that includes SiC as a main component, a step of forming a second electrode layer that is electrically connected to a first terminal of the vertical power semiconductor element and is harder than the first electrode layer on the first electrode layer, and a step of connecting a bonding wire to the second electrode layer.

A preferred embodiment of the present invention provides a semiconductor device including a semiconductor layer that has a first main surface at one side and a second main surface at another side, a first main surface electrode that includes a first electrode covering the first main surface and a second electrode having a higher hardness than the first electrode and covering the first electrode, and an oxide layer that covers the first main surface electrode.

A preferred embodiment of the present invention provides a method for manufacturing a semiconductor device including a step of preparing a semiconductor layer having a main surface, a step of forming a first main surface electrode that includes a first electrode and a second electrode on the main surface, by forming the first electrode on the main surface and forming the second electrode having a higher hardness than the first electrode on the first electrode, and a step of forming an oxide layer that covers an outer surface of the first main surface electrode.

The aforementioned as well as yet other objects, features, and effects of the present invention will be made clear by the following description of the preferred embodiments, with reference to the accompanying drawings.

### BRIEF DESCRIPTION OF DRAWINGS

FIG. 1 is a plan view of a semiconductor device according to a preferred embodiment.

FIG. 2 is a sectional view of the semiconductor device according to the preferred embodiment.

FIG. 3A is a sectional view of a manufacturing process of the semiconductor device according to the preferred embodiment.

FIG. 3B is a sectional view of the manufacturing process of the semiconductor device according to the preferred embodiment.

FIG. 3C is a sectional view of the manufacturing process of the semiconductor device according to the preferred embodiment.

FIG. 3D is a sectional view of the manufacturing process of the semiconductor device according to the preferred embodiment.

FIG. 3E is a sectional view of the manufacturing process of the semiconductor device according to the preferred embodiment.

FIG. 3F is a sectional view of the manufacturing process of the semiconductor device according to the preferred embodiment.

FIG. 4 is a sectional view of a modification example of the semiconductor device according to the preferred embodiment.

FIG. 5 is a perspective view of a semiconductor package according to a preferred embodiment.

FIG. 6 is a sectional view of a diode semiconductor device according to a preferred embodiment.

### DESCRIPTION OF EMBODIMENTS

### Preferred Embodiments of the Present Invention

shall now be described specifically with reference to the attached drawings. Each of the preferred embodiments described below illustrates a comprehensive or specific example. Numerical values, shapes, materials, constituent elements, arrangement positions of the constituent elements, connection forms of the constituent elements, steps, order of the steps, etc., described with the following preferred embodiments are examples and are not intended to limit the present disclosure. Among the constituent elements in the following preferred embodiments, a constituent element that is not described in an independent claim is described as an optional constituent element.

The respective attached drawings are schematic views and are not necessarily drawn precisely. For example, the scales, etc., of the attached drawings are not necessarily matched. In the attached drawings, arrangements that are substantially the same are provided with the same reference sign and redundant description is omitted or simplified.

In the present description, terms that represent a relationship between elements such as vertical, horizontal, etc., terms that represent shapes of elements such as rectangular, etc., and numerical ranges are not expressions expressing just strict meanings but are expressions meaning to include substantially equivalent ranges.

Also, in the present description, the terms “upper/above” and “lower/below” do not indicate an upper direction (vertically upper) and a lower direction (vertically lower) in terms of an absolute spatial recognition but are used as terms defined by a relative positional relationship based on an order of lamination in a laminated arrangement. Specifically, in the present description, descriptions are provided with a first main surface side at one side of a semiconductor layer being an upper side (above) and a second main surface side at another side being a lower side (below). In actual use of a semiconductor device (vertical transistor), the first main surface side may be a lower side (below) and the second main surface side may be an upper side (above). Or, the semiconductor device (vertical transistor) may be used in an orientation where the first main surface and the second main surface are inclined or orthogonal with respect to a horizontal plane.

Also, the terms “upper/above” and “lower/below” are applied in a case where two constituent elements are disposed at an interval from each other such that another constituent element is interposed between the two constituent elements as well as in a case where two constituent elements are disposed such that the two constituent elements are adhered closely to each other.

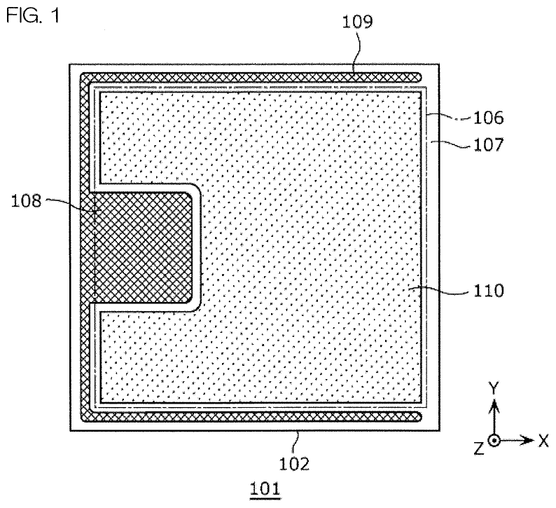

The arrangement of a semiconductor device according to the present preferred embodiment shall now be described. FIG. 1 is a plan view of a semiconductor device 101 according to the present preferred embodiment. The semiconductor device 101 includes a power semiconductor device (power semiconductor element) as an example of a functional device. In the following, an example where the semiconductor device 101 includes a vertical transistor is illustrated.

Referring to FIG. 1, the semiconductor device 101 has an SiC semiconductor layer 102 that includes an SiC (silicon carbide) monocrystal as an example of a wide bandgap semiconductor. In this embodiment, the SiC semiconductor layer 102 is formed to a chip of rectangular parallelepiped shape. The SiC semiconductor layer 102 includes a first main surface 103 at one side and a second main surface 104 at another side. The first main surface 103 is a device surface on which main structures of the functional device are formed. The second main surface 104 may be a mounting surface that faces a connection object when the semiconductor device 101 is connected to the connection object.

A length of one side of the SiC semiconductor layer 102 may be not less than 1 mm and not more than 10 mm (for example, not less than 2 mm and not more than 5 mm). An active region 106 and an outer region 107 are set in the SiC semiconductor layer 102. The active region 106 is a region in which a MISFET (metal insulator semiconductor field effect transistor) of a vertical type is formed. The outer region 107 is a region at an outer side of the active region 106.

The semiconductor device 101 includes a gate electrode 108, a gate finger 109, and a source electrode 110 that are respectively formed on the first main surface 103 of the SiC semiconductor layer 102. The gate electrode 108 and the source electrode 110 are each formed as an example of a first main surface electrode. The gate electrode 108 may be referred to as a gate pad and the source electrode 110 may be referred to as a source pad. In FIG. 1, the gate electrode 108, the gate finger 109, and the source electrode 110 are shown with hatching for clarification. The gate electrode 108, the gate finger 109, and the source electrode 110 may include aluminum or copper.

The gate electrode 108 is formed to a quadrilateral shape in plan view. The gate electrode 108 is led out from the outer region 107 into the active region 106 such as to cross a boundary region between the outer region 107 and the active region 106 in plan view. The gate finger 109 is formed in the outer region 107. The gate finger 109 is led out from the gate electrode 108 and extends as a band in the outer region 107.

The source electrode 110 is formed in the active region 106 at intervals from the gate electrode 108 and the gate finger 109. The source electrode 110 is formed to a recessed shape in plan view such as to cover a region of recessed shape demarcated by the gate electrode 108 and the gate finger 109. A gate voltage is applied to the gate electrode 108 and the gate finger 109. The gate voltage may be not less than 10 V and not more than 50 V (for example, approximately 30V). A source voltage is applied to the source electrode 110. The source voltage may be a reference voltage (for example, a GND voltage).

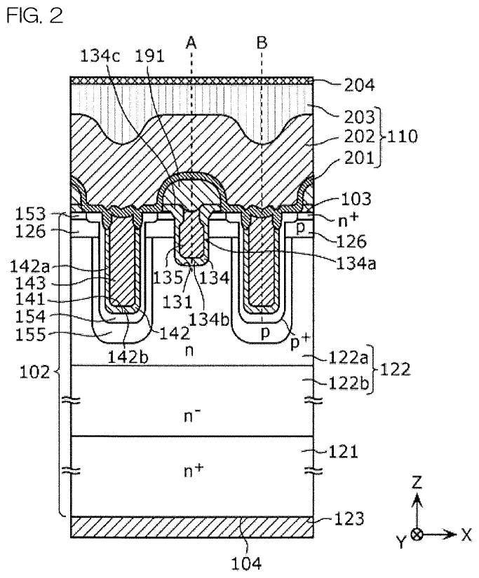

FIG. 2 is a sectional view of the SiC semiconductor layer 102 and is a sectional view taken along a first direction X of the MISFET in the active region 106. The first direction X is an arbitrary direction along the first main surface 103 (second main surface 104) of the SiC semiconductor layer 102. Referring to FIG. 2, in this embodiment, the SiC semiconductor layer 102 has a laminated structure that includes an SiC semiconductor substrate 121 of an n⁺-type and an SiC epitaxial layer 122 of an n-type. The SiC semiconductor substrate 121 is formed as a drain region of the MISFET. The SiC epitaxial layer 122 is formed as a drift region of the MISFET.

The SiC semiconductor substrate 121 forms the second main surface 104 of the SiC semiconductor layer 102. The SiC epitaxial layer 122 forms the first main surface 103 of the SiC semiconductor layer 102. The second main surface 104 of the SiC semiconductor layer 102 may be a ground surface. A thickness of the SiC semiconductor substrate 121 may be not less than 1 μm but less than 1000 μm. The thickness of the SiC semiconductor substrate 121 is preferably not more than 150 μm.

A thickness of the SiC epitaxial layer 122 may be not less than 1 μm and not more than 100 μm. The thickness of the SiC epitaxial layer 122 is preferably not more than 15 μm or not more than 10 μm. An n-type impurity concentration of the SiC epitaxial layer 122 is not more than the n-type impurity concentration of the SiC semiconductor substrate 121. The n-type impurity concentration of the SiC epitaxial layer 122 may be not less than 1.0×10¹⁵ cm⁻³ and not more than 1.0×10¹⁸ cm⁻³.

In this embodiment, the SiC epitaxial layer 122 has a plurality of region having different n-type impurity concentrations along a normal direction Z to the first main surface 103 of the SiC semiconductor layer 102. Specifically, the SiC epitaxial layer 122 includes a high concentration region 122a that is comparatively high in n-type impurity concentration and a low concentration region 122b that is lower in n-type impurity concentration than the high concentration region 122a.

The high concentration region 122a is formed in a region at the first main surface 103 side. The low concentration region 122b is formed in a region at the second main surface 104 side of the SiC semiconductor layer 102 with respect to the high concentration region 122a. An n-type impurity concentration of the high concentration region 122a may be not less than 1.0×10¹⁶ cm⁻³ and not more than 1.0×10¹⁸ cm³. An n-type impurity concentration of the low concentration region 122b may be not less than 1.0×10¹⁵ cm⁻³ and not more than 1.0×10¹⁶ cm⁻³. A thickness of the high concentration region 122a is not more than a thickness of the low concentration region 122b. Specifically, the thickness of the high concentration region 122a is less than the thickness of the low concentration region 122b.

The semiconductor device 101 includes a drain electrode 123 that covers the second main surface 104 of the SiC semiconductor layer 102. The drain electrode 123 is formed as an example of a second main surface electrode and may be referred to as a drain pad. A maximum voltage that is applicable across the source electrode 110 and the drain electrode 123 in an off state may be not less than 1000 V and not more than 10000 V.

The drain electrode 123 may include at least one among a Ti (titanium) layer, an Ni (nickel layer), an Au (gold) layer, or an Ag (silver) layer. The drain electrode 123 may have a four-layer structure that includes a Ti layer, an Ni layer, an Au layer, and an Ag layer that are laminated in that order from the second main surface 104 of the SiC semiconductor layer 102.

The drain electrode 123 may have a four-layer structure that includes a Ti layer, an A1 (aluminum) Cu (alloy of A1 and Cu) layer, an Ni layer, and an Au layer that are laminated in that order from the second main surface 104 of the SiC semiconductor layer 102. The drain electrode 123 may have a four-layer structure that includes a Ti layer, an AlSi (silicon) Cu (alloy of A1, Si, and Cu) layer, an Ni layer, and an Au layer that are laminated in that order from the second main surface 104 of the SiC semiconductor layer 102. The drain electrode 123 may have a laminated structure that includes a TiN (titanium nitride) layer or a Ti layer and a TiN layer in place of a Ti layer.

The semiconductor device 101 includes a body region 126 of a p-type that is formed in a surface layer portion of the first main surface 103 of the SiC semiconductor layer 102 in the active region 106. The body region 126 defines the active region 106. That is, in this embodiment, the body region 126 is formed in an entirety of a region that forms the active region 106 in the first main surface 103 of the SiC semiconductor layer 102. A p-type impurity concentration of the body region 126 may be not less than 1.0×10¹⁷ cm⁻³ and not more than 1.0×10²⁰ cm⁻³.

The semiconductor device 101 includes a plurality of gate trenches 131 that are formed in the surface layer portion of the first main surface 103 of the SiC semiconductor layer 102 in the active region 106. The plurality of gate trenches 131 are formed at intervals along the arbitrary first direction X. The plurality of gate trenches 131 are formed as bands extending along a second direction Y that intersects the first direction X. The plurality of gate trenches 131 are formed in stripes in plan view. A length of each gate trench 131 may be not less than 0.5 mm. In this embodiment, the length of each gate trench 131 is not less than 1 mm and not more than 10 mm (for example, not less than 2 mm and not more than 5 mm).

Each gate trench 131 penetrates through the body region 126 and reaches the SiC epitaxial layer 122. A bottom wall of each gate trench 131 is positioned inside the SiC epitaxial layer 122. Specifically, the bottom wall of each gate trench 131 is positioned in the high concentration region 122a of the SiC epitaxial layer 122. In regard to the normal direction Z to the first main surface 103 of the SiC semiconductor layer 102, a depth of the gate trench 131 may be not less than 0.5 μm and not more than 3 μm (for example, approximately 1 μm). The depth of the gate trench 131 is preferably not less than 0.5 μm and not more than 1.0 μm. A width in the first direction X of the gate trench 131 may be not less than 0.1 μm and not more than 2 μm (for example, approximately 0.5 μm). The width in the first direction X of the gate trench 131 is preferably not less than 0.1 μm and not more than 0.5 μm.

A gate insulating layer 134 and a gate electrode layer 135 is formed inside each gate trench 131. The gate insulating layer 134 includes silicon oxide. The gate insulating layer 134 may include a silicon nitride or other insulating film. The gate insulating layer 134 is formed as a film along an inner wall surface of the gate trench 131 such that a space of recessed shape is demarcated inside the gate trench 131.

The gate insulating layer 134 includes a first region 134a, a second region 134b, and a third region 134c. The first region 134a is formed along a side wall of the gate trench 131. The second region 134b is formed along the bottom wall of the gate trench 131. The third region 134c is formed along the first main surface 103 of the SiC semiconductor layer 102. A thickness of the first region 134a is less than a thickness of the second region 134b and a thickness of the third region 134c. The thickness of the first region 134a may be not less than 0.01 μm and not more than 0.2 μm. The thickness of the second region 134b may be not less than 0.05 μm and not more than 0.5 μm. The thickness of the third region 134c may be not less than 0.05 μm and not more than 0.5 μm. Obviously, the gate insulating layer 134 having a uniform thickness may be formed instead.

The gate electrode layer 135 is embedded in the gate trench 131 across the gate insulating layer 134. Specifically, the gate electrode layer 135 is embedded in the gate trench 131 such as to fill the space of recessed shape demarcated by the gate insulating layer 134. The gate electrode layer 135 is controlled by the gate voltage. The gate electrode layer 135 is electrically connected to the gate electrode 108 and the gate finger 109.

In a sectional view orthogonal to the direction (second direction Y) in which the gate trench 131 extends, the gate electrode layer 135 is formed as a wall that extends along the normal direction Z to the first main surface 103 of the SiC semiconductor layer 102. The gate electrode layer 135 may include a conductive polysilicon. The gate electrode layer 135 may include an n-type polysilicon or a p-type polysilicon as an example of a conductive polysilicon. The gate electrode layer 135 may include at least one type of substance among tungsten, aluminum, copper, aluminum alloy, or copper alloy in place of a conductive polysilicon.

The semiconductor device 101 includes a plurality of source trenches 141 that are formed in the first main surface 103 of the SiC semiconductor layer 102 in the active region 106. Each source trench 141 is formed in a region between two gate trenches 131 that are mutually adjacent. The plurality of source trenches 141 are respectively formed as bands extending along the second direction Y. The plurality of source trenches 141 are formed as stripes in plan view. In regard to the first direction X, a pitch between central portions of source trenches 141 that are mutually adjacent may be not less than 1.5 μm and not more than 3 μm.

Each source trench 141 penetrates through the body region 126 and reaches the SiC epitaxial layer 122. A bottom wall of each source trench 141 is positioned inside the SiC epitaxial layer 122. Specifically, the bottom wall of each source trench 141 is positioned in the high concentration region 122a. In this embodiment, a depth of the source trench 141 is not less than the depth of the gate trench 131. Specifically, the depth of the source trench 141 is greater than the depth of the gate trench 131.

In regard to the normal direction Z to the first main surface 103 of the SiC semiconductor layer 102, the depth of the source trench 141 may be not less than 0.5 μm and not more than 10 μm (for example, approximately 2 μm). A first direction width of the source trench 141 may be not less than 0.1 μm and not more than 2 μm (for example, approximately 0.5 μm). A source insulating layer 142 and a source electrode layer 143 are formed inside each source trench 141.

The source insulating layer 142 may include silicon oxide. The source insulating layer 142 is formed as a film along an inner wall surface of the source trench 141 such that a space of recessed shape is demarcated inside the source trench 141. The source insulating layer 142 includes a first region 142a and a second region 142b. The first region 142a is formed along a side wall of the source trench 141. The second region 142b is formed along the bottom wall of the source trench 141. A thickness of the first region 142a is less than a thickness of the second region 142b. The thickness of the first region 142a may be not less than 0.01 μm and not more than 0.2 μm. The thickness of the second region 142b may be not less than 0.05 μm and not more than 0.5 μm. Obviously, the source insulating layer 142 having a uniform thickness may be formed instead.

The source electrode layer 143 is embedded in the source trench 141 across the source insulating layer 142. Specifically, the source electrode layer 143 is embedded in the source trench 141 such as to fill the space of recessed shape demarcated by the source insulating layer 142. The source electrode layer 143 is controlled by the source voltage. A thickness of the source electrode layer 143 may be not less than 0.5 μm and not more than 10 μm (for example, approximately 1 μm).

The source electrode layer 143 preferably includes a polysilicon having a property close to SiC in material quality. Stress generated inside the SiC semiconductor layer 102 can thereby be reduced. The source electrode layer 143 may include the same conductive material type as the gate electrode layer 135. The source electrode layer 143 may include a conductive polysilicon. The source electrode layer 143 may include an n-type polysilicon or a p-type polysilicon as an example of a conductive polysilicon. The source electrode layer 143 may include at least one type of substance among tungsten, aluminum, copper, aluminum alloy, or copper alloy in place of a conductive polysilicon.

The semiconductor device 101 thus has trench gate structures and trench source structures. The trench gate structures include the gate trenches 131, the gate insulating layers 134, and the gate electrode layers 135. The trench source structures include the source trenches 141, the source insulating layers 142, and the source electrode layers 143.

The semiconductor device 101 includes source regions 153 of the n⁺-type that are formed in regions along the side walls of the gate trenches 131 in a surface layer portion of the body region 126. In this embodiment, in regard to the first direction X, a plurality of source regions 153 are formed along the side walls at one side and the side walls at another side of the gate trenches 131. An n-type impurity concentration of the source regions 153 may be not less than 1.0×10¹⁸ cm⁻³ and not more than 1.0×10²¹ cm⁻³.

The plurality of source regions 153 are respectively formed as bands extending along the second direction Y. The plurality of source regions 153 are formed as stripes in plan view. Each source region 153 is exposed from the side wall of a gate trench 131 and the side wall of a source trench 141.

The semiconductor device 101 includes a plurality of contact regions 154 of a p⁺-type that are formed in the surface layer portion of the first main surface 103 of the SiC semiconductor layer 102. A p-type impurity concentration of the contact regions 154 is greater than the p-type impurity concentration of the body region 126. The p-type impurity concentration of the contact regions 154 may be not less than 1.0×10¹⁸ cm⁻³ and not more than 1.0×10²¹ cm⁻³.

The plurality of contact regions 154 are formed along the side walls of the respective source trenches 141. The plurality of contact regions 154 are formed at intervals along the second direction Y. The plurality of contact regions 154 are formed at intervals from the gate trenches 131 along the first direction X. Each contact region 154 covers the side wall and the bottom wall of a source trench 141.

The semiconductor device 101 includes a plurality of p-type deep well regions 155 formed in the surface layer portion of the first main surface 103 of the SiC semiconductor layer 102. The deep well regions 155 are also referred to as withstand voltage control regions (withstand voltage holding regions) for adjusting a withstand voltage of the SiC semiconductor layer 102 in the active region 106. The respective deep well regions 155 are formed along the inner walls of the respective source trenches 141 such as to cover the contact regions 154.

A p-type impurity concentration of the deep well regions 155 may be substantially equal to the p-type impurity concentration of the body region 126. The p-type impurity concentration of the deep well regions 155 may exceed the p-type impurity concentration of the body region 126. The p-type impurity concentration of the deep well regions 155 may be less than the p-type impurity concentration of the body region 126. The p-type impurity concentration of the deep well regions 155 may be not more than the p-type impurity concentration of the contact regions 154. The p-type impurity concentration of the deep well regions 155 may be less than the p-type impurity concentration of the contact regions 154. The p-type impurity concentration of the deep well regions 155 may be not less than 1.0×10¹⁷ cm⁻³ and not more than 1.0×10¹⁹ cm⁻³.

Each deep well region 155 forms a pn-junction portion with the SiC semiconductor layer 102 (the high concentration region 122a of the SiC epitaxial layer 122). Depletion layers spread toward regions between a plurality of the gate trenches 131 that are mutually adjacent from the pn-junction portions. The depletion layers spread toward regions at the second main surface 104 side of the SiC semiconductor layer 102 with respect to the bottom walls of the gate trenches 131.

The semiconductor device 101 includes interlayer insulating layers 191 formed on the first main surface 103 of the SiC semiconductor layer 102. Each interlayer insulating layer 191 covers the active region 106 and the outer region 107 selectively. The interlayer insulating layer 191 may include silicon oxide or silicon nitride. The interlayer insulating layer 191 may include PSG (phosphor silicate glass) and/or BPSG (boron phosphor silicate glass) as an example of silicon oxide.

The semiconductor device 101 includes the source electrode 110 formed on the interlayer insulating layers 191. The source electrode 110 has a laminated structure that includes a first electrode layer 201, a second electrode layer 202, and a third electrode layer 203 that are laminated in that order from the first main surface 103 side (interlayer insulating layer 191 side) of the SiC semiconductor layer 102. The first electrode layer 201 may have a single layer structure that includes a titanium layer or a titanium nitride layer. The first electrode layer 201 may have a laminated structure that includes a titanium layer and a titanium nitride layer that are laminated in that order from the first main surface 103 side of the SiC semiconductor layer 102.

A thickness of the second electrode layer 202 is greater than a thickness of the first electrode layer 201. The second electrode layer 202 includes a conductive material having a lower resistance value than a resistance value of the first electrode layer 201. The second electrode layer 202 may include at least one among aluminum, copper, an aluminum alloy, or a copper alloy. The second electrode layer 202 may include at least one among an aluminum-silicon alloy, an aluminum-silicon-copper alloy, or an aluminum-copper alloy. In this embodiment, the second electrode layer 202 includes an aluminum-silicon-copper alloy. The first main surface 103 of the SiC semiconductor layer 102 (a front surface of a wafer) has an uneven structure due to the presence or non-presence of the interlayer insulating layers 191, etc., and a front surface of the second electrode layer 202 has an uneven structure (uneven portion) that is formed in conformance to the uneven structure mentioned above.

The third electrode layer 203 includes at least one among nickel (Ni) and copper (Cu). The third electrode layer 203 may have a single layer structure that includes a nickel layer or a copper layer. The third electrode layer 203 may have a laminated structure that includes a nickel layer and a copper layer. The third electrode layer 203 preferably includes a nickel layer. The third electrode layer 203 is harder than the second electrode layer 202. By providing the comparatively hard third electrode layer 203 on the second electrode layer 202, peeling of the source electrode 110 or destruction of a structure can be suppressed from occurring, for example, during wire bonding. That is, a mechanical strength can be improved.

For example, in regard to the normal direction Z to the first main surface 103 of the SiC semiconductor layer 102, a thickness of the third electrode layer 203 may be not less than 1 μm and not more than 10 μm. A front surface of the third electrode layer 203 is higher in flatness than the second electrode layer 202. Specifically, a difference between a highest position and a lowest position in a thickness direction of the third electrode layer 203 is smaller than a difference between a highest position and a lowest position in a thickness direction of the second electrode layer 202.

Specifically, the difference between the highest position and the lowest position in the thickness direction of the third electrode layer 203 in a single active cell (see FIG. 2) is less than the difference between the highest position and the lowest position in the thickness direction of the second electrode layer 202. A highest position is typically a front surface position of each layer at a central portion A of an interlayer insulating layer 191 and a lowest position is typically a front surface position of each layer at an intermediate position B of two interlayer insulating layers 191 that are adjacent. However, the structures formed on the first main surface 103 of the SiC semiconductor layer 102 (the front surface of the wafer) are various and therefore, the definitions of the highest position and the lowest position are not limited to the above.

The semiconductor device 101 includes an oxide layer 204 formed on the third electrode layer 203. The oxide layer 204 is constituted of a metal oxide layer that includes a metal oxide. Specifically, the oxide layer 204 is formed by oxidation of an outer surface of the source electrode 110 (first main surface electrode). That is, the oxide layer 204 includes an oxide of the source electrode 110. More specifically, the oxide layer 204 is formed by the third electrode layer 203 being oxidized and includes an oxide of at least one among nickel and copper. That is, the oxide layer 204 includes nickel oxide or copper oxide. Preferably, the oxide layer 204 has a thickness less than a thickness of the source electrode 110. Especially preferably, the oxide layer 204 has a thickness less than the thickness of the third electrode layer 203.

During wire bonding, the oxide layer 204 is removed by a bonding wire being connected and the bonding wire and the third electrode layer 203 are connected directly. In a region other than a connection portion of the bonding wire and the third electrode layer 203, the oxide layer 204 remains even after wire bonding. Therefore, in a state where the bonding wire is connected, the third electrode layer 203 has a covered portion covered by the oxide layer 204 and the connection portion connected to the bonding wire. The connection portion of the third electrode layer 203 is constituted of a removed portion at which at least a portion of the oxide layer 204 is removed and the bonding wire is directly connected electrically and mechanically.

Although specific illustration is omitted, the semiconductor device 101 includes the gate electrode 108 described above and the gate finger 109 described above that are formed on the interlayer insulating layers 191. As with the source electrode 110, the gate electrode 108 has a laminated structure that includes a first electrode layer 201, a second electrode layer 202, and a third electrode layer 203 that are laminated in that order from the first main surface 103 side (interlayer insulating layer 191 side) of the SiC semiconductor layer 102. The oxide layer 204 described above is also formed on an outer surface (the third electrode layer 203) of the gate electrode 108.

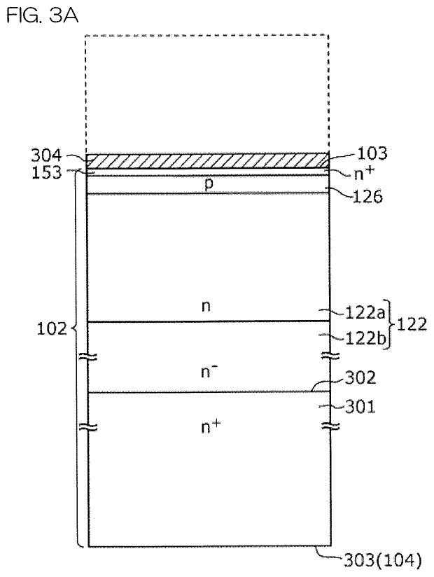

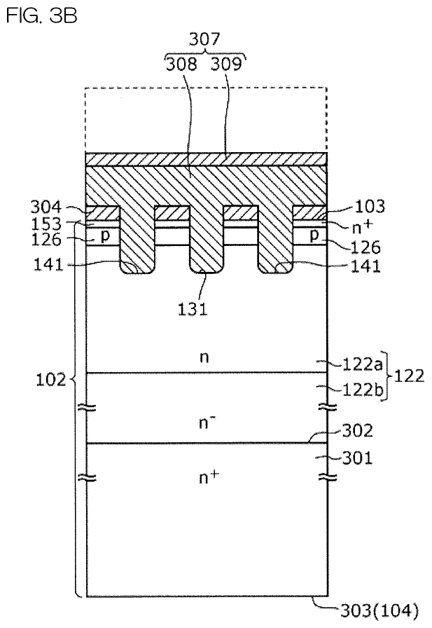

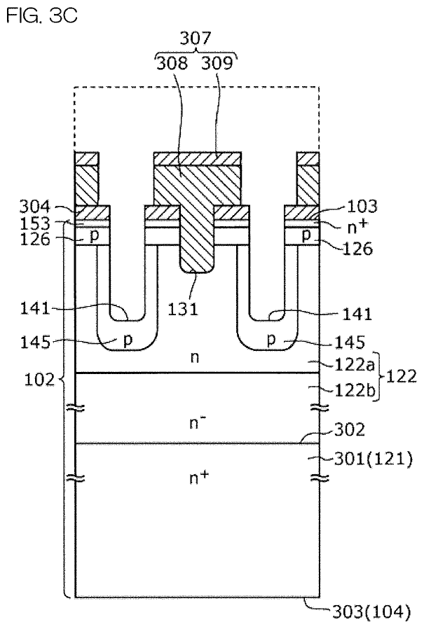

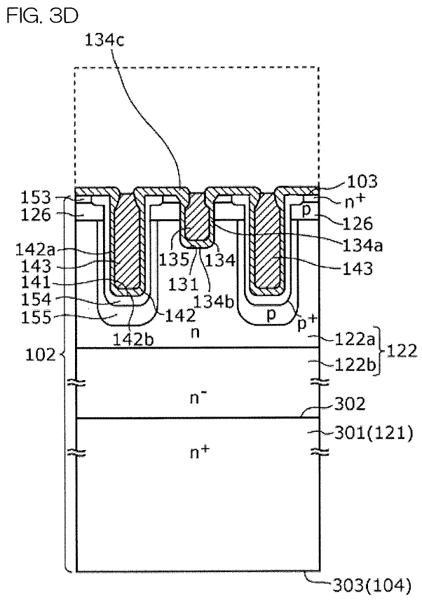

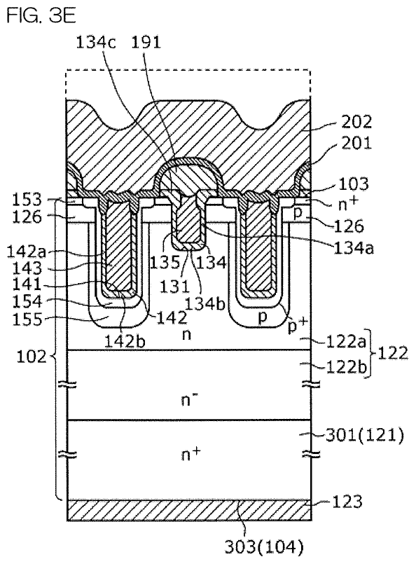

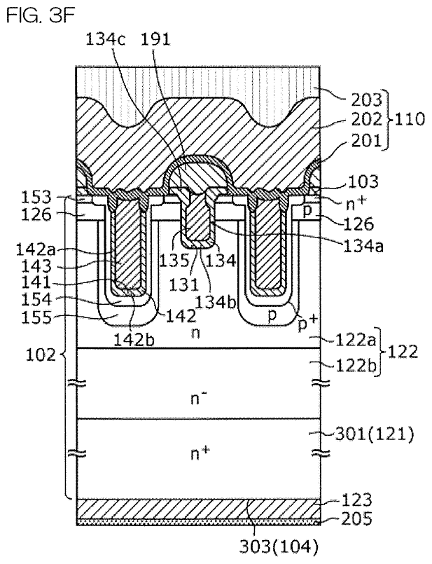

Next, a manufacturing process of the semiconductor device 101 shall be described. FIG. 3A to FIG. 3F are sectional views of an example of a manufacturing process of the semiconductor device 101 shown in FIG. 2.

First, referring to FIG. 3A, an SiC semiconductor wafer 301 of the n⁺-type that is to be a base of the SiC semiconductor substrate 121 of the n⁺-type is prepared. The SiC semiconductor wafer 301 has a first wafer main surface 302 at one side and a second wafer main surface 303 at another side. Next, the SiC epitaxial layer 122 is formed on the first wafer main surface 302 of the SiC semiconductor wafer 301. The SiC epitaxial layer 122 is formed by growing SiC from above the first wafer main surface 302 of the SiC semiconductor wafer 301 by an epitaxial growth method.

In this step, the SiC epitaxial layer 122 having the high concentration region 122a and the low concentration region 122b is formed by adjusting an added amount of the n-type impurity. The SiC semiconductor layer 102 that includes the SiC semiconductor wafer 301 and the SiC epitaxial layer 122 is thereby formed. The SiC semiconductor layer 102 includes the first main surface 103 and the second main surface 104. A description shall now be provided using the SiC semiconductor layer 102, the first main surface 103, and the second main surface 104.

Next, the body region 126 of the p-type is formed in the surface layer portion of the first main surface 103 of the SiC semiconductor layer 102. In this step, the body region 126 is formed across an entirety of the surface layer portion of the first main surface 103 of the SiC semiconductor layer 102. The body region 126 is formed by introduction of the p-type impurity into the first main surface 103 of the SiC semiconductor layer 102.

Next, the source regions 153 of the n⁺-type are formed in a surface layer portion of the body region 126. The source regions 153 are formed by introduction of the n-type impurity into the surface layer portion of the body region 126. In this step, the source regions 153 are formed across an entirety of a surface layer portion of the first main surface 103 of the SiC semiconductor layer 102. Next, a hard mask 304 is formed on the first main surface 103 of the SiC semiconductor layer 102. The hard mask 304 may include silicon oxide. The hard mask 304 may be formed by a CVD (chemical vapor deposition) method or a thermal oxidation treatment method. In this step, the hard mask 304 is formed by the thermal oxidation treatment method.

Next, referring to FIG. 3B, unnecessary portions of the SiC semiconductor layer 102 are removed by an etching method (for example, a dry etching method) via a resist mask. In this step, unnecessary portions of the SiC epitaxial layer 122 are removed. The gate trenches 131 and the source trenches 141 are thereby formed. Next, a mask 307 is formed. The mask 307 fills the gate trenches 131, the source trenches 141, and the outer region 107 and covers the first main surface 103 of the SiC semiconductor layer 102. The mask 307 has a laminated structure that includes a polysilicon layer 308 and an insulating layer 309. The insulating layer 309 includes silicon oxide.

The polysilicon layer 308 may be formed by a CVD method. The insulating layer 309 may be formed by a CVD method or a thermal oxidation treatment method. In this step, the insulating layer 309 is formed by the thermal oxidation treatment method on the polysilicon layer 308.

Next, unnecessary portions of the mask 307 are removed by an etching method (for example, a dry etching method) via a resist mask. The source trenches 141 and the outer region 107 are thereby exposed from the mask 307. Next, unnecessary portions of the SiC semiconductor layer 102 are removed by an etching method (for example, a dry etching method) via the mask 307. The source trenches 141 and the outer region 107 are thereby dug in further.

Next, the deep well regions 155 are formed in the surface layer portion of the first main surface 103 of the SiC semiconductor layer 102. The deep well regions 155 are formed by introduction of the p-type impurity into the first main surface 103 of the SiC semiconductor layer 102. The p-type impurity is introduced into the first main surface 103 of the SiC semiconductor layer 102 via the mask 307.

Next, referring to FIG. 3D, the mask 307 is removed. Next, the contact regions 154 are formed in the surface layer portion of the first main surface 103 of the SiC semiconductor layer 102. The contact regions 154 are formed by introduction of the p-type impurity into the first main surface 103 of the SiC semiconductor layer 102. The p-type impurity is introduced into the first main surface 103 of the SiC semiconductor layer 102 via a resist mask.

Next, a base insulating layer that is to be a base of the gate insulating layers 134 and the source insulating layers 142 is formed on the first main surface 103 of the SiC semiconductor layer 102. The base insulating layer may include silicon oxide. The base insulating layer may be formed by a CVD method or a thermal oxidation method. Next, a base conductor layer that is to be a base of the gate electrode layers 135 and the source electrode layers 143 is formed on the first main surface 103 of the SiC semiconductor layer 102. The base conductor layer fills the gate trenches 131, the source trenches 141, and the outer region 107 and covers the first main surface 103 of the SiC semiconductor layer 102.

The base conductor layer may include a polysilicon. The base conductor layer may be formed by a CVD method. The CVD method may be an LP-CVD (low pressure CVD) method. Next, unnecessary portions of the base conductor layer are removed. The unnecessary portions of the base conductor layer are removed until the base insulating layer is exposed. The unnecessary portions of the base conductor layer may be removed by an etch-back method with the base insulating layer as an etching stop layer.

The unnecessary portions of the base conductor layer may be removed by an etching method (for example, a wet etching method) via a mask having a predetermined pattern. The gate electrode layers 135 and the source electrode layers 143 are thereby formed.

Next, referring to FIG. 3E, the interlayer insulating layers 191 are formed on the first main surface 103 of the SiC semiconductor layer 102. The interlayer insulating layers 191 cover the active region 106 and the outer region 107 collectively. The interlayer insulating layers 191 may include silicon oxide or silicon nitride. The interlayer insulating layers 191 may be formed by a CVD method. Next, unnecessary portions of the interlayer insulating layers 191 are removed. The unnecessary portions of the interlayer insulating layers 191 may be removed by an etching method (for example, a dry etching method) via a resist mask.

Next, unnecessary portions of the base insulating layer that is exposed from the interlayer insulating layers 191 are removed. The unnecessary portions of the base insulating layer may be removed by an etching method (for example, a dry etching method). The base insulating layer is thereby divided into the gate insulating layers 134 and the source insulating layers 142.

Next, a base electrode layer that is to be a base of the gate electrode 108 and the source electrode 110 is formed on the interlayer insulating layers 191. In this step, the first electrode layers 201 and the second electrode layers 202 are formed. In this step, first, the first electrode layers 201 are formed on the interlayer insulating layers 191. The first electrode layers 201 include a step of forming titanium layers and titanium nitride layers in that order on the interlayer insulating layers 191. The titanium layers and the titanium nitride layers are formed by a sputtering method. The first electrode layers 201 each having a single layer structure constituted of a titanium layer or a titanium nitride layer may be formed instead.

Next, the second electrode layers 202 are formed on the first electrode layers 201. The second electrode layers 202 may include an aluminum-silicon-copper alloy. The second electrode layers 202 may be formed by a sputtering method.

Next, the drain electrode 123 is formed on the second main surface 104 of the SiC semiconductor layer 102. In this step, a step of forming at least one among a Ti layer, an Ni layer, an Au layer, or an Ag layer as the drain electrode layer 123 may be included. The Ti layer, the Ni layer, the Au layer, or the Ag layer may be formed by a sputtering method. The step of forming the drain electrode 123 may include a step of forming a Ti layer, an Ni layer, an Au layer, and an Ag layer in that order from the second main surface 104 of the SiC semiconductor layer 102. The Ti layer, the Ni layer, the Au layer, and the Ag layer may be formed by a sputtering method.

Next, referring to FIG. 3F, the third electrode layers 203 are formed on the second electrode layers 202. The third electrode layers 203 may include at least one among nickel and copper. The third electrode layers 203 each have a single layer structure that includes a nickel layer or a copper layer. The third electrode layers 203 may each have a laminated structure that includes a nickel layer and a copper layer.

In this step, first, a rear surface tape 205 is adhered to a surface of the drain electrode 123 on the second main surface 104 of the SiC semiconductor layer 102. Next, the third electrode layers 203 are formed on the second electrode layers 202 by a plating method. The plating method may, for example, be an electroless plating method. After forming the third electrode layers 203, the rear surface tape 205 is peeled off. After the third electrode layers 203 are formed, the oxide layers 204 are formed by oxidation on the front surfaces of the third electrode layers 203. The step of forming the oxide layers 204 may be included in the step of forming the third electrode layers 203.

Thereafter, the SiC semiconductor layer 102 (SiC semiconductor wafer 301) is cut selectively along dicing lines (dicing streets). A plurality of the semiconductor devices 101 are thereby cut out from a single SiC semiconductor wafer 301. A step of bonding wires or other lead wires (conductive connecting members) to the third electrode layers 203 is then performed on each semiconductor device 101 after dicing. The semiconductor device 101 is formed through steps including the above.

Although here, the third electrode layers 203 are formed on just the first main surface 103 side by adhesion of the rear surface tape 205, electrode layers (third electrode layers 203) may instead be formed on both the first main surface 103 side and the second main surface 104 side by performing the electroless plating method without adhering the rear surface tape 205. That is, an electrode layer corresponding to the third electrode layers 203 may cover the drain electrode 123.

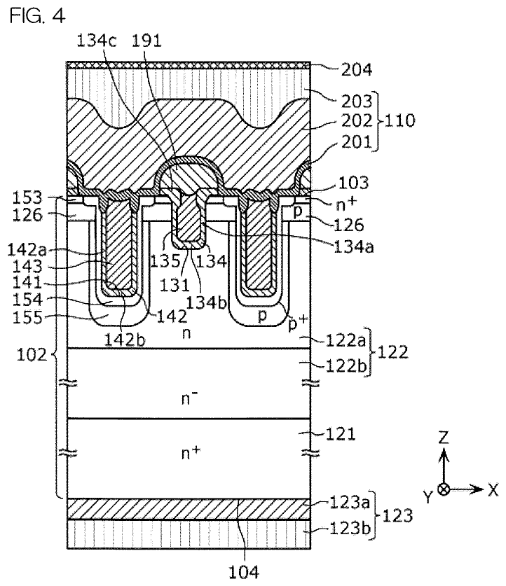

FIG. 4 is a sectional view of the arrangement of the semiconductor device 101 in this case. As shown in this figure, the drain electrode 123 includes a fourth electrode layer 123a and a fifth electrode layer 123b that are formed in that order from the second main surface 104 of the SiC semiconductor layer 102. The fourth electrode layer 123a corresponds to the drain electrode 123 shown in FIG. 2.

The fourth electrode layer 123a is constituted, for example, of the same material as the second electrode layers 202. The fourth electrode layer 123a and the second electrode layers 202 are, for example, constituted of aluminum. Also, the fifth electrode layer 123b is constituted of the same material as the third electrode layers 203. The fifth electrode layer 123b is formed by the electroless plating method in the same step as the third electrode layers 203.

The fifth electrode layer 123b may include at least one among nickel and copper. The fifth electrode layer 123b may have a single layer structure that includes a nickel layer or a copper layer. The fifth electrode layer 123b may have a laminated structure that includes a nickel layer and a copper layer. As with the front surfaces of the third electrode layers 203, a surface of the fifth electrode layer 123b may be covered by an oxide layer 204. That is, the semiconductor device 101 may include an oxide layer (the oxide layer 204 at the second main surface 104 side) that covers the surface of the drain electrode 123 at the second main surface 104 side (the surface of the fifth electrode layer 123b).

Next, the arrangement of a semiconductor package 401 that includes the semiconductor device 101 shall be described. FIG. 5 is a perspective view, as seen through a sealing body 407, of the semiconductor package 401 in which the semiconductor device 101 described above is incorporated.

The semiconductor package 401 includes a semiconductor chip 402, a pad portion 403, a heat spreader 404, a plurality (three in this embodiment) of terminals 405, a plurality (three in this embodiment) of lead wires 406, and the sealing body 407. The semiconductor device 101 described above is applied as the semiconductor chip 402.

The pad portion 403 includes a metal plate. The pad portion 403 may include aluminum, copper, etc. The pad portion 403 is formed to a quadrilateral shape in plan view. The pad portion 403 has a planar area that is not less than a planar area of the semiconductor chip 402. The drain electrode 123 of the semiconductor chip 402 is electrically connected to the pad portion 403 by die bonding.

The heat spreader 404 is connected to one side of the pad portion 403. In this embodiment, the pad portion 403 and the heat spreader 404 are formed by a single metal plate. A penetrating hole 404a is formed in the heat spreader 404. The penetrating hole 404a is formed to a circular shape. The plurality of terminals 405 are aligned along a side at an opposite side to the heat spreader 404 with respect to the pad portion 403. The plurality of terminals 405 each include a metal plate that extends as a band. The terminals 405 may include aluminum, copper, etc. The plurality of terminals 405 include a first terminal 405A, a second terminal 405B, and a third terminal 405C.

The first terminal 405A, the second terminal 405B, and the third terminal 405C are aligned at intervals along the side at the opposite side to the heat spreader 404 with respect to the pad portion 403. The first terminal 405A, the second terminal 405B, and the third terminal 405C extends as bands in a direction orthogonal to an alignment direction thereof. The second terminal 405B and the third terminal 405C sandwich the first terminal 405A from both sides.

The plurality of lead wires 406 may be bonding wires, etc. In this embodiment, the plurality of lead wires 406 include a lead wire 406A, a lead wire 406B, and a lead wire 406C. The lead wire 406A is electrically connected to the gate electrode 108 of the semiconductor chip 402 and the first terminal 405A. The lead wire 406B is electrically connected to the source electrode 110 of the semiconductor chip 402 and the second terminal 405B. The lead wire 406C is electrically connected to the pad portion 403 and the third terminal 405C. If the bonding wires are constituted of aluminum, preferably, at least the front surfaces of the third electrode layers (third electrode layers 203) are constituted of nickel.

The sealing body 407 seals the semiconductor chip 402, the pad portion 403, and the plurality of lead wires 406 such as to expose portions of the heat spreader 404, and of the plurality of terminals 405. The sealing body 407 includes a sealing resin. The sealing body 407 is formed to a rectangular parallelepiped shape. The form of the semiconductor package 401 is not limited to the form shown in FIG. 5.

As the semiconductor package 401, an SOP (small outline package), a QFN (quad flat non-lead package), a DFP (dual flat package), a DIP (dual inline package), a QFP (quad flat package), an SIP (single inline package), an SOJ (small outline J-leaded package), or any of various semiconductor package related to these may be applied.

Although in the description above, an example where the functional device (semiconductor element) included in the semiconductor device 101 is a vertical transistor was illustrated, the semiconductor device 101 may include a vertical diode instead. The semiconductor device 101 may include one of either of a transistor and a diode or may include both a transistor and a diode.

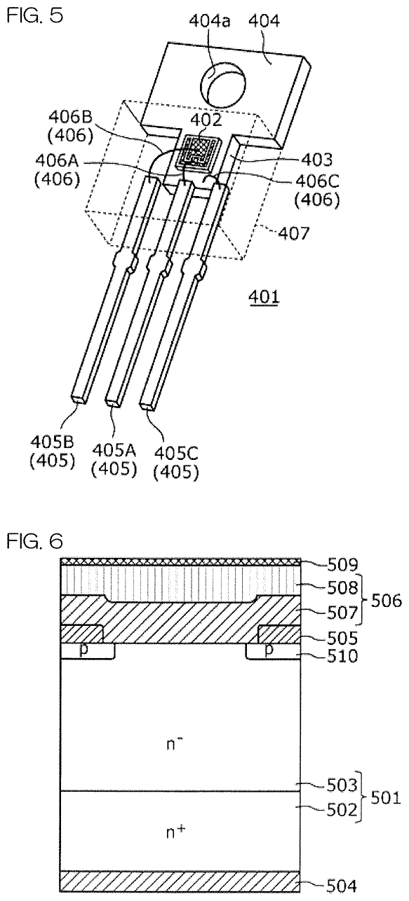

FIG. 6 is a sectional view of a semiconductor device 101 that includes a diode. As shown in FIG. 6, this semiconductor device 101 includes an SiC semiconductor layer 501. The SiC semiconductor layer 501 includes an SiC semiconductor substrate 502 of the n⁺-type and an SiC epitaxial layer 503 of an n⁻-type. An impurity density of the SiC semiconductor substrate 502 is, for example, approximately 1.0×10¹⁸ cm⁻³ to approximately 1.0×10²¹ cm⁻³. An impurity density of the SiC epitaxial layer 503 is, for example, approximately 1.0×10¹⁴ cm⁻³ to approximately 1.0×10¹⁶ cm⁻³. The SiC epitaxial layer 503 may have a buffer layer that is formed on the SiC semiconductor substrate 502 and a drift layer formed on the buffer layer.

The semiconductor device 101 includes a cathode electrode 504 that covers a rear surface ((000-1)C-plane) of the SiC semiconductor substrate 502. The cathode electrode 504 is formed as an example of the second main surface electrode. The cathode electrode 504 covers an entirety of the rear surface of the SiC semiconductor substrate 502. The cathode electrode 504 is connected to a cathode terminal.

The semiconductor device 101 includes a field insulating film 505 formed on a front surface ((0001) Si-plane) of the SiC epitaxial layer 503. Although the field insulating film 505 is constituted of SiO2 (silicon oxide), it may be constituted of another insulating material such as silicon nitride (SiN), etc., instead.

The semiconductor device 101 includes an anode electrode 506 that is formed on the field insulating film 505. The anode electrode 506 is formed as an example of the first main surface electrode. The anode electrode 506 is connected to an anode terminal. The anode electrode 506 includes a first electrode layer 507 and a second electrode layer 508. The first electrode layer 507 is formed on the SiC epitaxial layer 503 and the field insulating film 505. The second electrode layer 508 is formed on the first electrode layer 507.

The first electrode layer 507 may, for example, include at least one among aluminum, copper, aluminum alloy, or copper alloy. The first electrode layer 507 may include at least one among an aluminum-silicon alloy, an aluminum-silicon-copper alloy, or an aluminum-copper alloy.

The second electrode layer 508 may include at least one among nickel and copper. The second electrode layer 508 may have a single layer structure that includes a nickel layer or a copper layer. The second electrode layer 508 may have a laminated structure that includes a nickel layer and a copper layer. The second electrode layer 508 preferably includes a nickel layer. The second electrode layer 508 is harder than the first electrode layer 507. By providing the comparatively hard second electrode layer 508 on the first electrode layer 507, peeling of the anode electrode 506 or destruction of a structure can be suppressed from occurring, for example, during wire bonding. That is, a mechanical strength can be improved.

The semiconductor device 101 includes an oxide layer 509 formed on the second electrode layer 508. The oxide layer 509 is constituted of a metal oxide layer that includes a metal oxide. Specifically, the oxide layer 509 is formed by oxidation of an outer surface of the anode electrode 506 (first main surface electrode). That is, the oxide layer 509 includes an oxide of the anode electrode 506. More specifically, the oxide layer 509 is formed by the second electrode layer 508 being oxidized and includes an oxide of at least one among a nickel layer and a copper layer. That is, the oxide layer 509 includes nickel oxide or copper oxide. Preferably, the oxide layer 509 has a thickness less than a thickness of the anode electrode 506. Especially preferably, the oxide layer 509 has a thickness less than the thickness of the second electrode layer 508.

During wire bonding, the oxide layer 509 is removed by a bonding wire being connected and the bonding wire and the second electrode layer 508 are connected directly. Ina region other than a connection portion of the bonding wire and the second electrode layer 508, the oxide layer 204 remains even after wire bonding. Therefore, in a state where the bonding wire is connected, the second electrode layer 508 has a covered portion covered by the oxide layer 509 and the connection portion connected to the bonding wire. The connection portion of the second electrode layer 508 is constituted of a removed portion at which at least a portion of the oxide layer 509 is removed and the bonding wire is directly connected electrically and mechanically.

The semiconductor device 101 includes a JTE (junction termination extension) structure 510 (impurity region) of the p-type that is formed in a vicinity of a front surface (front layer portion) of the SiC epitaxial layer 503. The JTE (junction termination extension) structure 510 is formed such as to contact the first electrode layer 507 of the anode electrode 506.

As described above, the semiconductor devices according to the present preferred embodiments have the following features. The semiconductor device 101 according to one mode of the present invention is a semiconductor device that includes a vertical power semiconductor element as shown in FIG. 2. The semiconductor device 101 includes the SiC semiconductor layer 102, first electrode layers (the second electrode layers 202), second electrode layers (the third electrode layers 203), a third electrode layer (the drain electrode 123), and the oxide layers 204.

The SiC semiconductor layer 102 has the first main surface 103 and the second main surface 104 at the opposite side to the first main surface 103 and includes SiC as a main component. The first electrode layers (second electrode layers 202) are formed on the first main surface 103 side of the SiC semiconductor layer 102. The second electrode layers (third electrode layers 203) are formed on the first electrode layers (second electrode layers 202) and are electrically connected to first terminals of the vertical power semiconductor element. The second electrode layers (third electrode layers 203) are harder than the first electrode layers (second electrode layers 202).

The third electrode layer (drain electrode 123) is formed at the second main surface 104 side of the SiC semiconductor layer 102 and is electrically connected to a second terminal of the vertical power semiconductor element. The oxide layers 204 are formed on the front surfaces of the second electrode layers (third electrode layers 203). With this structure, destruction of a structure, for example, during wire bonding can be suppressed by the second electrode layers (third electrode layers 203). The mechanical strength can thus be improved.

For example, the second electrode layers (third electrode layers 203) are constituted of nickel (Ni) or copper (Cu) and the oxide layers 204 are constituted of an oxide of nickel or copper. For example, the vertical power semiconductor element may be a vertical transistor, a first terminal may be a source terminal, and the second terminal may be a drain terminal. The vertical power semiconductor element may be a vertical transistor, a first terminal may be a gate terminal, and the second terminal may be a drain terminal. As shown in FIG. 6, the vertical power semiconductor element may be a vertical diode, one of either of the first terminal and the second terminal may be an anode terminal, and the other may be a cathode terminal.

For example, the second electrode layers (third electrode layers 203) are formed of plating layers. For example, as shown in FIG. 4, the semiconductor device 101 further includes a fourth electrode layer (the fifth electrode layer 123b). The fourth electrode layer (fifth electrode layer 123b) is formed on a surface of the third electrode layer (fourth electrode layer 123a) at the opposite side to the SiC semiconductor layer 102 side. The fourth electrode layer (fifth electrode layer 123b) is harder than the third electrode layer (fourth electrode layer 123a). For example, the semiconductor package according to one mode of the present invention includes the semiconductor device 101 (semiconductor chip 402) and bonding wires (the lead wires 406) connected to the second electrode layers (third electrode layers 203) as shown in FIG. 5.

The method for manufacturing a semiconductor device according to one mode of the present invention is a method for manufacturing the semiconductor device 101 that includes a vertical power semiconductor element. This method for manufacturing the semiconductor device includes a first step, a second step, and a third step. In the first step, the first electrode layers (second electrode layers 202) are formed on the first main surface 103 side of the SiC semiconductor layer 102. In the second step, the second electrode layers (third electrode layers 203) that are electrically connected to the first terminals of the vertical power semiconductor element and are harder than the first electrode layers (second electrode layers 202) are formed on the first electrode layers (second electrode layers 202). In the third step, the bonding wires (lead wires 406) are connected to the second electrode layers (third electrode layers 203). According to this manufacturing method, destruction of a structure during wire bonding can be suppressed by the second electrode layers (third electrode layers 203). The mechanical strength can thus be improved.

For example, in the step of forming the second electrode layers (third electrode layers 203) (second step), the second electrode layers (third electrode layers 203) are formed by a plating method. In the manufacturing method described above, the step of connecting the bonding wires (lead wires 406) (third step) may be included in a method for manufacturing a semiconductor package.

Although semiconductor devices according to one or a plurality of modes have been described based on the preferred embodiments above, the present disclosure is not limited to these preferred embodiments. As long as the spirit and scope of the present disclosure is not departed from, embodiments in which various modifications that one skilled in the art can arrive at are applied to the preferred embodiments and embodiments constructed by combination of the constituent elements in different preferred embodiments are also included within the scope of the present disclosure.

Also, various modifications, replacements, additions, omissions, etc., can be performed within the scope of the claims or the scope of equivalents thereof on the respective preferred embodiments described above. In regard to industrial applicability, the present invention can be applied to semiconductor device, semiconductor packages, etc.

Examples of features that are extracted from the present description and drawings are indicated below. A semiconductor device, a semiconductor package, and methods for manufacturing these by which mechanical strength can be improved are provided by the following. Although alphanumeric characters within parenthesis in the following express corresponding constituent elements, etc., in the preferred embodiments described above, these are not meant to limit the scopes of the respective items to the preferred embodiments.

[A1] A semiconductor device (101) including a vertical power semiconductor element, the semiconductor device (101) comprising: a semiconductor layer (102, 501) that has a first main surface (103) and a second main surface (104) at an opposite side to the first main surface (103) and includes SiC as a main component; a first electrode layer (202, 507) that is formed on the first main surface (103) side of the semiconductor layer (102, 501); a second electrode layer (203, 508) that is formed on the first electrode layer (202, 507), is electrically connected to a first terminal of the vertical power semiconductor element, and is harder than the first electrode layer (202, 507); a third electrode layer (123, 123a, 123b, 504) that is formed on the second main surface (104) side of the SiC semiconductor layer (102, 501) and is electrically connected to a second terminal of the vertical power semiconductor element; and an oxide layer (204, 509) that is formed on a front surface of the second electrode layer (203, 508).

[A2] The semiconductor device (101) according to A1, wherein the second electrode layer (203, 508) is constituted of nickel or Cu, and the oxide layer (204, 509) is constituted of an oxide of nickel or Cu.

[A3] The semiconductor device (101) according to A1 or A2, wherein the vertical power semiconductor element is a vertical transistor, the first terminal is a source terminal, and the second terminal is a drain terminal.

[A4] The semiconductor device (101) according to any one of A1 to A3, wherein the second electrode layer (203, 508) is formed by plating.

[A5] The semiconductor device (101) according to any one of A1 to A4, wherein the semiconductor device (101) further comprising: a fourth electrode layer (123b) that is formed on a surface of the third electrode layer (123, 123a, 123b, 504) at an opposite side to the semiconductor layer (102, 501) and is harder than the third electrode layer (123, 123a, 123b, 504).

[A6] A semiconductor package (401) comprising: the semiconductor device (101) according to any one of A1 to A5; and a bonding wire (406) that is connected to the second electrode layer (203, 508).

[A7] A method for manufacturing a semiconductor device (101) including a vertical power semiconductor element, the method for manufacturing the semiconductor device (101) comprising: a step of forming a first electrode layer (202, 507) at a first main surface (103) side of a semiconductor layer (102, 501) that includes SiC as a main component; a step of forming a second electrode layer (203, 508) that is electrically connected to a first terminal of the vertical power semiconductor element and is harder than the first electrode layer (202, 507) on the first electrode layer (202, 507); and a step of connecting a bonding wire (406) to the second electrode layer (203, 508).

[A8] The method for manufacturing the semiconductor device (101) according to A7, wherein the second electrode layer (203, 508) is formed by plating in the step of forming the second electrode layer (203, 508).

[B1] A semiconductor device (101) comprising: a semiconductor layer (102, 501) that has a first main surface (103) at one side and a second main surface (104) at another side; a second electrode (108, 110, 506) that includes a first electrode (202, 507) covering the first main surface (103) and a second electrode (203, 508) having a higher hardness than the first electrode (202, 507) and covering the first electrode (202, 507); and an oxide layer (204, 509) that covers the second electrode (108, 110, 506).

[B2] The semiconductor device (101) according to B1, wherein the oxide layer (204, 509) is constituted of a metal oxide layer that includes a metal oxide.

[B3] The semiconductor device (101) according to B1 or B2, wherein the oxide layer (204, 509) includes an oxide of the second electrode (108, 110, 506).

[B4] The semiconductor device (101) according to any one of B1 to B3, wherein the oxide layer (204, 509) is thinner than the second electrode (108, 110, 506).

[B5] The semiconductor device (101) according to any one of B1 to B4, wherein the oxide layer (204, 509) is thinner than the second electrode (203, 508).

[B6] The semiconductor device (101) according to anyone of B1 to B5, wherein the oxide layer (204, 509) includes an oxide of the second electrode (203, 508).

[B7] The semiconductor device (101) according to B6, wherein the second electrode (203, 508) includes at least one among nickel and copper and the oxide layer (204, 509) includes an oxide of at least one among nickel and copper.

[B8] The semiconductor device (101) according to any one of B1 to B7, wherein the second electrode (203, 508) is constituted of a plating layer.

[B9] The semiconductor device (101) according to anyone of B1 to B8, wherein the semiconductor layer (102, 501) includes a wide bandgap semiconductor as a main component.

[B10] The semiconductor device (101) according to anyone of B1 to B9, wherein the semiconductor layer (102, 501) includes SiC as a main component.

[B11] The semiconductor device (101) according to any one of B1 to B10, further comprising: a functional device that is formed on the semiconductor layer (102, 501); and wherein the second electrode (108, 110, 506) is electrically connected to the functional device.

[B12] The semiconductor device (101) according to B11, wherein the functional device includes a transistor that has a source, and the second electrode (108, 110, 506) includes a source electrode (110) that is electrically connected to the source of the transistor.

[B13] The semiconductor device (101) according to B11, wherein the functional device includes a transistor that has a gate, and the second electrode (108, 110, 506) includes a gate electrode (108) that is electrically connected to the gate of the transistor.

[B14] The semiconductor device (101) according to B11, wherein the functional device includes a diode that has an anode, and the second electrode (108, 110, 506) includes an anode electrode (506) that is electrically connected to the anode of the diode.

[B15] The semiconductor device (101) according to anyone of B1 to B14, further comprising: a second main surface electrode (123, 123a, 123b, 504) that covers the second main surface (104).

[B16] The semiconductor device (101) according to B15, wherein the second main surface electrode (123, 123a, 123b, 504) includes a third electrode (123a) that covers the second main surface (104) and a fourth electrode (123b) that has a higher hardness than the third electrode (123a) and covers the third electrode (123a).

[B17] A semiconductor package (401) comprising: the semiconductor device (101) according to any one of B1 to B16 and a bonding wire (406) that is electrically connected to the second electrode (108, 110, 506).

[B18] The semiconductor package (401) according to B17, wherein the bonding wire (406) penetrates through the oxide layer (204, 509) and is electrically and mechanically connected to the second electrode (203, 508), and the second electrode (108, 110, 506) has a covered portion covered by the oxide layer (204, 509) and a connected portion directly connected to the bonding wire (406).

[B19] A method for manufacturing a semiconductor device (101) comprising: a step of preparing a semiconductor layer (102, 501) having a main surface (103); a step of forming a second electrode (108, 110, 506) that includes a first electrode (202, 507) and a second electrode (203, 508) on the main surface (103), by forming the first electrode (202, 507) on the main surface (103) and forming the second electrode (203, 508) having a higher hardness than the first electrode (202, 507) on the first electrode (202, 507); and a step of forming an oxide layer (204, 509) that covers an outer surface of the second electrode (108, 110, 506).

[B20] A method for manufacturing a semiconductor package (401) comprising: the method for manufacturing the semiconductor device (101) according to B19; and a step of connecting a bonding wire (406) to the second electrode (108, 110, 506).

### REFERENCE SIGNS LIST

101 semiconductor device
102 SiC semiconductor layer
103 first main surface
104 second main surface
108 gate electrode (first main surface electrode)
110 source electrode (first main surface electrode)
123 drain electrode (second main surface electrode)
123a fourth electrode layer
123b fifth electrode layer
201 first electrode layer
202 second electrode layer
203 third electrode layer
204 oxide layer
401 semiconductor package
402 semiconductor chip (semiconductor device)
406 lead wire (bonding wire)
501 SiC semiconductor layer
504 cathode electrode (second main surface electrode)
506 anode electrode (first main surface electrode)
507 first electrode layer
508 second electrode layer
509 oxide layer

1. A semiconductor device comprising:
a semiconductor layer that has a first main surface at one side and a second main surface at another side;
a first main surface electrode that includes a first electrode covering the first main surface and a second electrode having a higher hardness than the first electrode and covering the first electrode; and
an oxide layer that covers the first main surface electrode.

2. The semiconductor device according to claim 1, wherein the oxide layer is constituted of a metal oxide layer that includes a metal oxide.

3. The semiconductor device according to claim 1, wherein the oxide layer includes an oxide of the first main surface electrode.

4. The semiconductor device according to claim 1, wherein the oxide layer is thinner than the first main surface electrode.

5. The semiconductor device according to claim 1, wherein the oxide layer is thinner than the second electrode.

6. The semiconductor device according to claim 1, wherein the oxide layer includes an oxide of the second electrode.

7. The semiconductor device according to claim 6, wherein the second electrode includes at least one among nickel and copper and
the oxide layer includes an oxide of at least one among nickel and copper.

8. The semiconductor device according to claim 1, wherein the second electrode is constituted of a plating layer.

9. The semiconductor device according to claim 1, wherein the semiconductor layer includes a wide bandgap semiconductor as a main component.

10. The semiconductor device according to claim 1, wherein the semiconductor layer includes SiC as a main component.

11. The semiconductor device according to claim 1, further comprising:
a functional device that is formed in the semiconductor layer; and
wherein the first main surface electrode is electrically connected to the functional device.

12. The semiconductor device according to claim 11, wherein the functional device includes a transistor that has a source and
the first main surface electrode includes a source electrode that is electrically connected to the source of the transistor.

13. The semiconductor device according to claim 11, wherein the functional device includes a transistor that has a gate and
the first main surface electrode includes a gate electrode that is electrically connected to the gate of the transistor.

14. The semiconductor device according to claim 11, wherein the functional device includes a diode that has an anode and
the first main surface electrode includes an anode electrode that is electrically connected to the anode of the diode.

15. The semiconductor device according to claim 1, further comprising:
a second main surface electrode that covers the second main surface.

16. The semiconductor device according to claim 15, wherein the second main surface electrode includes a third electrode that covers the second main surface and
a fourth electrode that has a higher hardness than the third electrode and covers the third electrode.

17. A semiconductor package comprising:
the semiconductor device according to claim 1; and
a bonding wire that is electrically connected to the first main surface electrode.

18. The semiconductor package according to claim 17, wherein the bonding wire penetrates through the oxide layer and is electrically and mechanically connected to the second electrode, and
the first main surface electrode has a covered portion covered by the oxide layer and a connected portion directly connected to the bonding wire.

19. A method for manufacturing a semiconductor device comprising:
a step of preparing a semiconductor layer having a main surface;
a step of forming a first main surface electrode that includes a first electrode and a second electrode on the main surface, by forming the first electrode on the main surface and forming the second electrode having a higher hardness than the first electrode on the first electrode; and
a step of forming an oxide layer that covers an outer surface of the first main surface electrode.

20. A method for manufacturing a semiconductor package comprising:
the method for manufacturing the semiconductor device according to claim 19; and
a step of connecting a bonding wire to the first main surface electrode.
